(19) United States
(12) Patent Application Publication
(10) Pub. No.: US 2018/0218073 A1
(43) Pub. Date: Aug. 2, 2018

(54) SYSTEM AND METHOD FOR SECURE TRANSMISSION OF SIGNALS FROM A CAMERA

(71) Applicant: Cloud Crowding Corp., New York, NY (US)

(72) Inventors: Murray B. WILSHINSKY, Jerusalem (IL); David Yanovsky, Tallinn (EE); Teimuraz NAMORADZE, Tallinn (EE)

(21) Appl. No.: 15/742,410

(22) PCT Filed: Jul. 7, 2016
(86) PCT No.: PCT/US2016/041349

§ 371 Date: Jan. 5, 2018

Related U.S. Application Data
(60) Provisional application No. 62/189,769, filed on Jul. 8, 2015.

(51) Int. Cl. G06F 17/30; H04N 7/18

(52) U.S. Cl. CPC G06F 17/30858; H04N 7/181; H03M 13/3761; G06F 17/30194; G06F 17/3082

(57) ABSTRACT

According to the invention herein, the method for secure transmission of signals from a camera includes the steps of: separating output video signals from processing units inside the camera into discrete pieces; and dispersing these discrete pieces among multiple transmission streams to multiple storage nodes wherein no transmission stream has sufficient data for reconstructing the media files. In a preferred embodiment, the multiple storage nodes are located in diverse geographic locations. Preferably, there is error correction coding of the discrete pieces.

### FIELD OF THE DISCLOSURE

The subject matter of the present disclosure generally relates to IP cameras, and more particularly IP camera systems for secure data storage and transmission of video signals.

### BACKGROUND OF THE DISCLOSURE

IP (internet protocol) security cameras are commonly implemented to continuously broadcast video files captured using the camera over a network. Analog cameras used in conjunction with an analog to digital video recorder (DVR) can also be configured to deliver the same results and broadcast video files over a network as well.

There are various benefits and drawbacks associated with IP cameras. Similarly, analog-based camera systems also have benefits and drawbacks compared to IP cameras. Regardless of the shape, style, or size of a camera, the guts are all the same inside, but with slightly different components used. The variations of the inner workings of the different types of cameras is further described herein.

As would be appreciated by those in the art, an analog security camera 105 often consists of four main components; a lens 110 fitted to its holder 115, an image sensor 120 and a DSP (digital signal processor) 125, as shown in FIG. 1. The most common types of image sensors are CMOS (complementary metal-oxide-semiconductor) and CCD (charge-coupled device). CCD sensors have a uniform output, and thus generally have better image quality with low noise. With a CMOS sensor, on the other hand, uniformity is much lower, resulting in a lesser image quality and the images tend to be higher in noise. CCD sensors are more sensitive to light and CMOS sensors need more light to create a low noise image. The architecture of CCD and CMOS cameras would be understood by those in the art.

IP camera technology generally uses CCD or CMOS sensors. CMOS sensors tend to be a little bit cheaper than CCD, which is why most IP cameras in the market are currently CMOS. IP camera manufacturers are using the same CMOS image sensors used by mobile phone manufacturers. Due to the high usage of CMOS image sensor in the mobile phone industry, the cost of CMOS has become inexpensive.

The DSP (digital signal processor) is the “brain” of most cameras. It takes in raw analog image data from the image sensor and converts it to a digital signal. DSPs allow advanced features for the camera, like digital noise reduction, and wide dynamic range. If a camera includes a DSP and is configured to send the signal over an analog transmission medium, the image is converted back to analog for it to be transmitted, say, over a coaxial cable. For instance, FIG. 1 shows the analog camera including a BNC analog video output connection 125. The disadvantage of that process is that image quality is deteriorated. Every time data is encoded or decoded, some data bits are lost, causing less image clarity. In practice, the DSP is not necessary to obtain video output from a camera, rather, sometimes it is just used to enhance video image quality at night, in color and other common industry requirements.

The more components there are inside a camera, the more expensive the camera becomes. There are lots of analog cameras in the marketplace at low prices. Those cameras are often using CMOS image sensors, without any DSPs.

Furthermore, the technology behind IP security cameras can differ from conventional computer webcams, which are also often used to capture video for transmission over IP networks. Computer webcams commonly include only the image sensors, which capture a raw video file and transmit the data through USB cables. Furthermore, webcams often require a software application running on the computer (and not the camera) that utilizes the computer processor to encode the analog video signal into a digital format. IP cameras, on the other hand, often have their own CPU (central processing unit) and components necessary to implement the digital encoding, decoding, processing algorithms and the like.

FIG. 2 is a high level diagram illustrating an exemplary configuration of an IP camera 200. The analog components 205 of the camera are encompassed by a dashed line, and the remaining components are provided to facilitate IP connectivity of the IP camera and transmission of the captured imagery over a IP network connection 240. An IP security camera often is connected to a web server. In other words, it has the capacity to stream video independently from a computer. That is why similar to a computer, memory components (e.g., memory/storage 225 and flash memory 230) and a CPU 220 exist within a IP camera to handle video compression, host web-server firmware, de-interlace preprocessing, noise filtering and so on, as would be understood by those in the art.

Often, IP cameras are not connected directly to a digital video recorder for surveillance recording; rather, they are connected on a local area network or a wide area network through a router. For instance, FIG. 3 illustrates a conventional configuration of a local network including multiple IP cameras 300 connected by a network 315 that also includes a router 310 connected thereto. As shown in FIG. 3, a computer or a standalone NVR (network video recorder) 315 is also connected on the same network 315, and can be configured to pick up the video streaming through the network and use that digital stream to record it digitally on the hard drive (not shown).

Returning to FIG. 2, the video audio codec 210 takes a video data file captured by the camera and digitally compresses it using a specific type of compression algorithm. Some IP cameras have multiple streaming capabilities, where the video codec will compress each data file input to multiple video files such as H.264, MPEG4, or MJPEG at the same time.

By comparison, in analog cameras (e.g., analog camera 100 of FIG. 1), the DSP can often encode the analog signal to digital signal without compressing the video file. Ultimately, in the exemplary IP camera configuration of FIG. 2, the digital video is streamed through the network, processed at the computer, and stored digitally. Basically, video remains digital and no unnecessary conversions are made resulting in superior image quality.

IP cameras are intelligent devices that include many beneficial features. They compress video images to minimize video streaming over the network. IP cameras use frame rate control technology which sends images at a specified frame rate, so that only necessary frames are sent, whereas analog cameras stream the video data through the analog cables. The downside of using IP cameras is that the network bandwidth can limit the number of cameras that can be on the network without overloading it.

The reason IP security cameras exist is because the technological world of analog is shrinking. Even though analog cameras are still better sellers in the security surveillance industry, IP cameras are increasing in popularity. Prices of IP security cameras in comparison to analog have kept analog cameras ahead thus far. That trend has started to shift, as IP high definition camera prices have dropped drastically within the past 2 years. IP security cameras are superior to analog cameras; they provide better video quality, can utilize existing LAN area network, and have far greater capabilities than analog cameras.

Irrespective of whether an Analog security camera or IP camera is utilized, streaming image data captured by a camera over a digital communications network (e.g., in a digitized format using an IP protocol) has a number of drawbacks. In particular, the IP network connection over which the data is transmitted is vulnerable to security breaches even when encrypted. This can be a single point of weakness. In addition, transmission of higher resolution video requires higher bandwidth, and typical implementations in networks generally have poor bandwidth utilization. These limitations are particularly evident where video data is stored on remote storage systems, for instance cloud-based storage.

Cloud storage solutions are also highly vulnerable to “outages” that can result from disruptions of Internet communications between the enterprise client and its cloud storage systems. Cloud storage solutions based on storage of video files in one server location also make disaster recovery a potential pitfall if the server location is compromised. If replication and backup are also handled in the same physical server location, the problem of failure and disaster recovery could pose a real danger of massive data loss to the enterprise.

Current technology cloud storage solutions often require the storage overhead of replication and backup to ensure the safety of the stored data. Large amounts of required data redundancy adds a tremendous overhead in costs to maintain the storage capacity in the cloud. The need for such redundancy not only increases cost, but also introduces new problems for data security. In addition, all this redundancy also brings with it performance decreases as cloud servers use replication constantly in all server data transactions.

As Internet connections have improved in their ability to handle high throughputs of data, more security video is stored remotely and video streaming has become a very popular way to provide access to the remotely stored video content. Cloud storage plays an important role in many video storage and video access schemes. Typically, the media content resides on a company's web server. When requested by a user, the media content is streamed over the Internet in a steady stream of successive data segments that are received by the client in time to display the next segment of the video file, resulting in what appears to be seamless playback of the audio or video to the user.

Current video streaming technology stores a complete copy of the entire media file on a web or media server to which the client connects to receive the stream of data. Data losses during the transmission process can easily interrupt the transfer process and halt the output of the video on the client computer. To avoid such problems, the prior art technology often will place the same video file on multiple server nodes, and multiple data centers throughout the world, whether they be public or private, so the user can connect to a server node near them. While this is necessary to insure the steady data transfer rates needed in the face of data packet loss due to connectivity issues, deploying multiple copies of the same file on many servers throughout the world places a major burden on video hosting providers.

The subject matter of the present disclosure is directed to mitigating and/or overcoming one or more of the problems set forth above and to facilitate a faster and more secure video data storage and transmission method, and more particularly to providing for a more secure data storage and transmission method using IP cameras configured to store video files in remote storage locations.

### BRIEF SUMMARY OF THE DISCLOSURE

In general, one innovative aspect of the subject matter described in this specification can be embodied in a method for secure transmission of signals from an IP camera. The method includes the step of separating an output video signal received from a processing unit inside said camera into discrete pieces using one or more processors of the camera. The method also includes the step of dispersing, using the one or more processors and a communication network interface of the camera, said discrete pieces among multiple distributed storage network nodes using multiple transmission streams. In addition, the transmission streams are transmitted over a communication network. In addition, no transmission stream has sufficient data for reconstructing said output video signal.

Another innovative aspect of the subject matter described in this specification can be embodied in an IP camera configured to securely transmit signals over an IP communication network. The camera comprises an imaging component including a lens, an image sensor configured to capture video imagery and one or more signal processing units configured to generate an output video signal from the captured imagery. The camera also includes a non-transitory memory having a client application in the form of machine readable instructions stored therein. In addition, the camera includes a network interface configured to connect the IP camera to a communication network. In addition, the camera includes one or more processors coupled to the imaging component and the network interface. The one or more processors execute the client software application and are configured to receive the output video signal from the imaging component and separate the output video signal into discrete pieces. The one or more processors are also configured to disperse, using the network interface, said discrete pieces among multiple distributed storage network nodes using multiple transmission streams. In particular, the transmission streams are transmitted over the communication network and wherein no transmission stream has sufficient data for reconstructing said output video signal.

The details of one or more embodiments of the subject matter described in this specification are set forth in the accompanying drawings and the description below. Other features, aspects, and advantages of the subject matter will become apparent from the description, the drawings, and the claims.

### BRIEF DESCRIPTION OF THE DRAWINGS

FIG. 1 is a schematic diagram of an exemplary analog security camera;

FIG. 2 is a high level diagram illustrating an exemplary configuration of an IP camera 200;

FIG. 3 is an exemplary security camera system including a plurality of IP security cameras;

FIG. 4A, is a high level diagram illustrating exemplary IP camera system according to an exemplary embodiment;

FIG. 4B, is a high level diagram illustrating the exemplary IP camera system of FIG. 4A according to an exemplary embodiment;

FIG. 5 is a flow diagram illustrating a process for secure transmission and storage of video signals using an IP camera according to an exemplary embodiment;

FIG. 6A is a schematic diagram of layers of an exemplary IP Camera and storage system according to an exemplary embodiment.

FIG. 6B is a diagram showing the various stages of video file processing according to an exemplary embodiment;

FIG. 7A is a diagram of a first section of file processing according to an exemplary embodiment.

FIG. 7B is a diagram of the erasure coding of file slices to produce slice fragments for dispersal according to an exemplary embodiment;

FIG. 7C is a detailed diagram of the upload process of a file to data storage nodes according to an exemplary embodiment;

FIG. 8 is a chart outlining various steps undertaken during file processing according to an exemplary embodiment;

FIG. 9 is a high level diagram illustrating an exemplary IP camera connected to a storage network using multiple communications channels according to an exemplary embodiment;

FIG. 10 is a high level diagram illustrating a conventional IP camera system connected to a storage network over a communication network;

FIG. 11, is a high level diagram illustrating an exemplary IP camera connected to a storage network according to an exemplary embodiment;

FIG. 12 is a high level diagram illustrating storage network nodes and dynamic delivery of discrete pieces of an IP Camera Video file during an upload and download process according to an exemplary embodiment; and

FIG. 13 is a chart of the various detailed steps undertaken during a download process of data from data storage to a client, according to an exemplary embodiment.

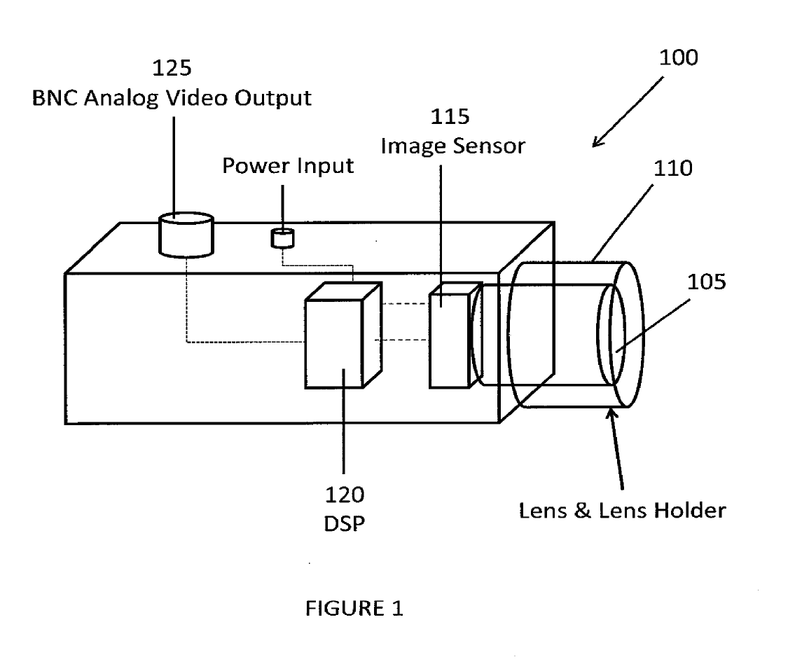

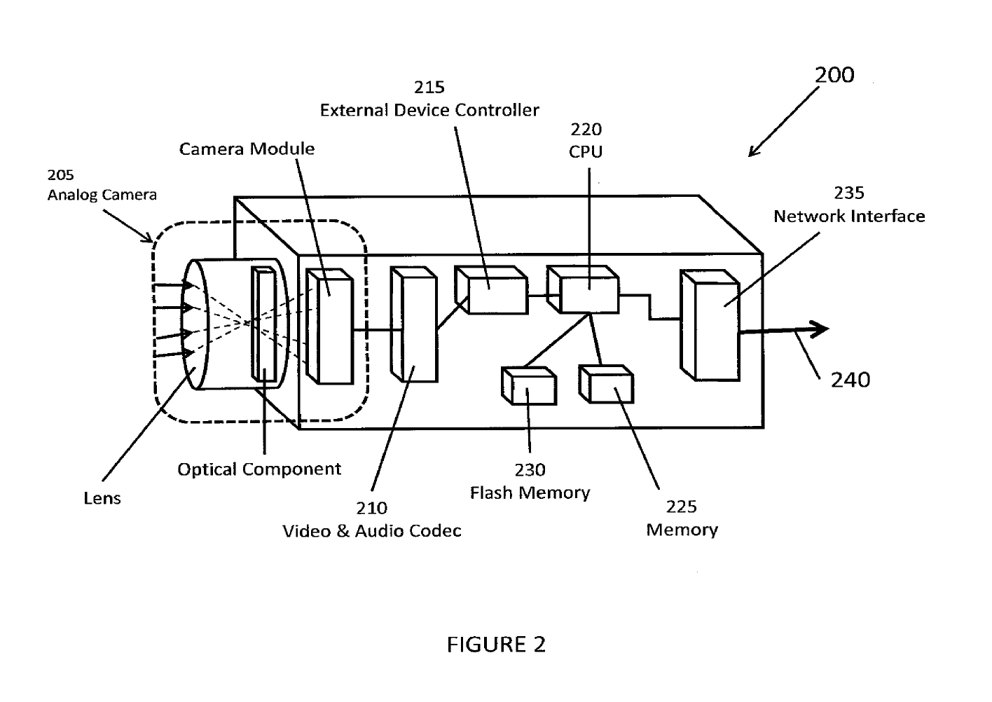

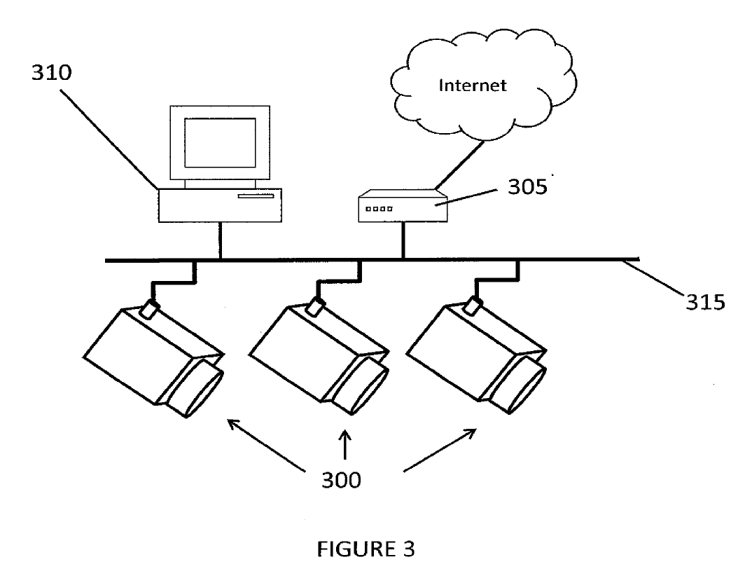

### DETAILED DESCRIPTION

Disclosed herein are network connected security camera systems, referred to as an IP camera system, and related methods for processing, secure transmission and storage of video signals from the camera system. In particular, the disclosed IP cameras implement methods that include steps for breaking up each video data file into discrete pieces, which are then stored on a plurality of dispersed networked storage nodes. According to one aspect, video signals captured by the IP camera is disassembled into file slice fragments using object storage technology. The disclosed IP camera systems also disperse the discrete pieces among multiple transmission streams and send the discrete pieces to multiple storage nodes. In a preferred embodiment, the multiple storage nodes are distributed, for instance, they are located in diverse geographic locations.

In some implementations, the resulting file slice fragments are encrypted, and optimized for error correction using erasure coding, before dispersal to the series of cloud servers. Moreover, in some implementations, the bandwidth used by the IP camera to transfer the video file can be optimized. This dispersal approach creates a “virtual hard drive” device in which a video file is not stored in a single physical device, but is spread out among a series of physical devices in the cloud which each only contain encrypted “fragments” of the file. These features also makes it possible to maximize the number of cameras that are used in the system without overloading the available network connections (e.g., the IP network and associated communication networks). Therefore, the bandwidth is more effectively utilized. Further, the transmission streams can also be optimized. In addition, in some preferred embodiments, multiple transmission lines can be used simultaneously or to provide redundancy in case of a failure. Moreover, in some implementations, the servers used for data storage in the cloud can be selected to optimize for both speed of data throughput and data security and reliability.

For retrieval, the encrypted and dispersed file slice fragments can be retrieved by a client computing device and rebuilt into the original file. Access of the file for the purposes of moving, deleting, reading or editing the video file is accomplished by reassembling the file fragments rapidly in real time. This approach provides numerous improvements in speed of data transfer and access, data security and data availability. It can also make use of existing hardware and software infrastructure and offers substantial cost reductions in the field of storage technology.

While the dispersed storage of data, in particular, the encoding and storage of camera video data on cloud servers is one particularly useful application, the same technology is applicable to configurations in which the video data can be stored on multiple storage devices which can be connected by any possible communications technology such as LAN's or WAN's. The speed and security benefits of the disclosed technology could remain when implemented using the devices of an information technology (IT) data center, where the final storage devices are multiple physical hard disks or multiple virtual hard disks. The multiple storage devices can also be spread across multiple individual users in cyberspace, with files stored on multiple physical or virtual hard disks which are available in the network. In each case, the speed of data transfer and security of data stored in the system are greatly enhanced.

Uses for the disclosed subject matter include primary storage needs where the files are uploaded and accessed without server-side processing. In accordance with the disclosed embodiments, this includes storage of the video content captured by the IP cameras such that the video data that can be made available for access through the Internet.

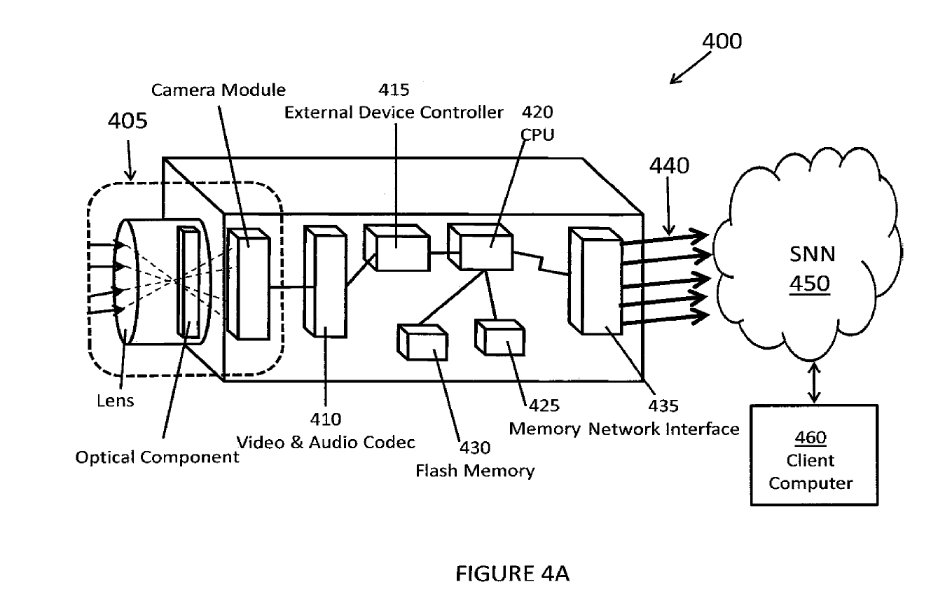

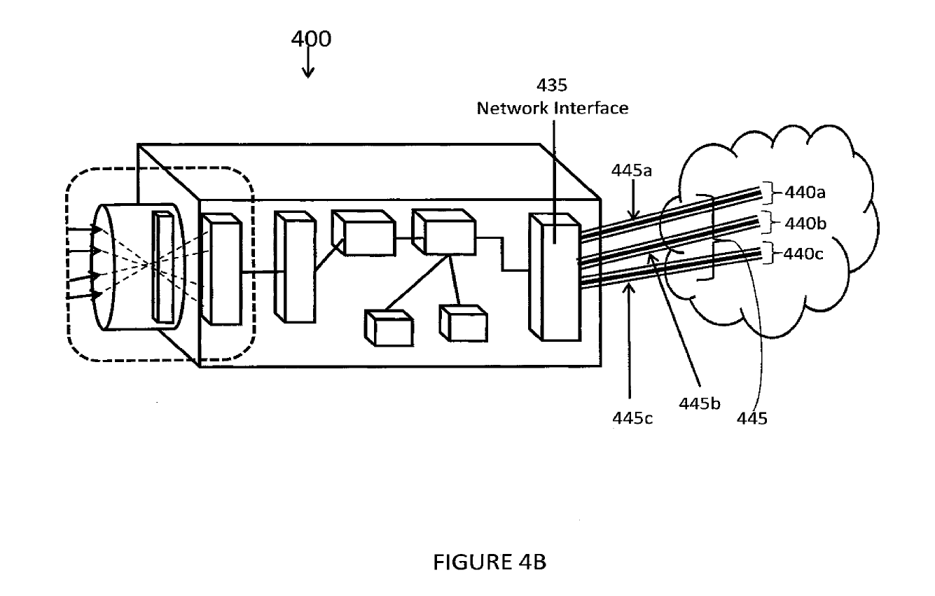

FIG. 4A, is a high level diagram illustrating the basic structure of an exemplary networked/IP camera 400 (e.g., an IP camera) for secure transmission and storage of video signals in accordance with one or more of the disclosed embodiments. It should be appreciated that the term IP camera refers to various types of camera systems configured to be connected to a data network such as a LAN or other IP network so as to transmit the video data over the network. As shown in FIG. 4A, the exemplary IP camera 400 can include analog camera components 405 encompassed by a dashed line that are configured to capture the analog video imagery. The remaining components of the camera 400 are provided to process the captured video images into video data files and also facilitate IP connectivity of the camera thereby enabling transmission of the video data files over an IP network connection as further described herein. As shown in FIG. 4A, the camera can include memory components (e.g., non-transitory computer-readable memory/storage 425 and flash memory 430) and a CPU 420. As would be understood by those in the art, the CPU can include one or more processors that are configured by executing instructions in the form of one or more software modules to perform various operations. These operations can include video compression, de-interlace preprocessing, noise filtering, hosting web-server firmware, and so on. In accordance with the disclosed embodiments, the CPU can also execute a client application that configures the CPU to process, encode and transmit video files captured by the camera over one or more communication networks (not shown) for storage in a distributed storage node network (SNN) 450, as further described herein. Examples of communication networks include a local area network (“LAN”) and a wide area network (“WAN”), an inter-network (e.g., the Internet), and peer-to-peer networks (e.g., ad hoc peer-to-peer networks).

The SNN 450 can include various cloud storage centers that can be operated by commercial cloud resource providers. The number and identity of the storage nodes in the SNN can be optionally selected by the CPU to optimize the latency and security of the storage configuration by choosing storage nodes that exhibit the best average latency and availability from the IP Camera's location.

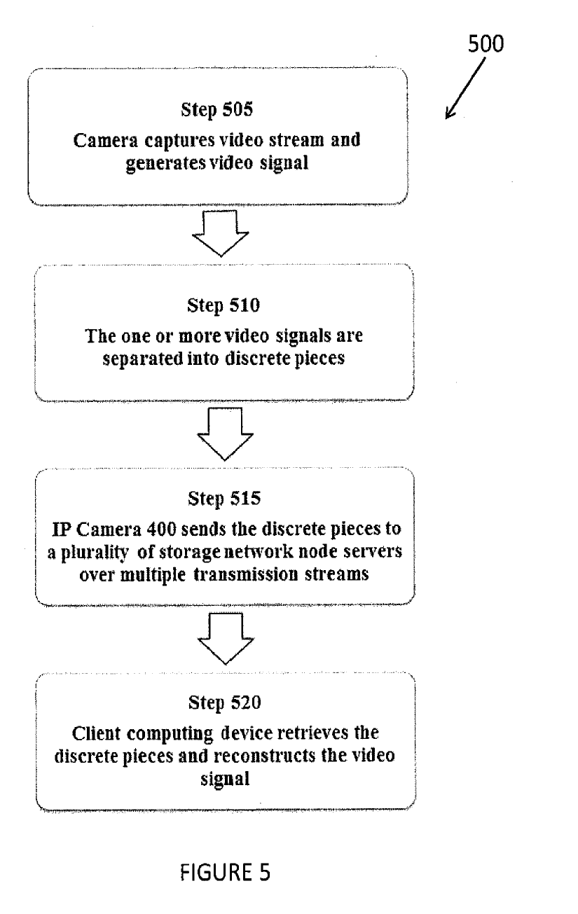

The exemplary features and functionality of the camera 400 are further described herein with continued reference to the various system components depicted in FIG. 4A. An example process for secure transmission and storage of video signals using an IP camera in accordance with one or more of the disclosed embodiments, is shown in FIG. 5.

The process begins at step 505, where the camera captures a stream of images and the stream (i.e., the video) is processed into one or more video data files, which are also referred to herein as video signals. As noted above, video processing can include processing the images by a video/audio codec 410 and the CPU 420 and other such hardware and/or software modules in order to compress, encode and otherwise translate the imagery into one or more digitized video files. Each video data file can represent a segment of streaming video signals captured by the camera and can be stored locally in memory 425 at least temporarily (e.g., as a video file). The size of each individual video file can vary depending on the implementation and prescribed settings relating to one or more of a prescribed temporal length of each video segment and a prescribed file size for each video segment. Such settings can be user defined, for instance, by a user using a user-interface during an initial IP Camera set-up/configuration step. In addition or alternatively these and other settings can be set as a default or can be dynamically adjusted by the IP Camera CPU based on the operation of the system and system or network constraints (e.g., bandwidth, local and network storage availability and the like). Accordingly, in some implementations, small video files (e.g., files having a limited temporal duration or file-size) can be sequentially captured, processed and transferred into distributed storage in near-real time, as further described herein. As a result, a user can also be provided with near-real time access to the video files from the distributed storage network. It can also be appreciated that, in addition or alternatively, larger or longer video segments can be incrementally captured, processed and stored to the distributed storage system in a similar fashion.

Then at step 510, the one or more video files are separated into discrete pieces. The discrete pieces are also referred to herein as “file slice fragments” or, more generally, “fragments.” It should be appreciated that the video signal can include multiple signals from one or more signal processing components inside the camera. Accordingly, each individual signal can be split into discrete pieces. In addition or alternatively, multiple video signals can be combined and split into pieces. Splitting the signal into discrete pieces can further include digitizing the video signal.

In accordance with one or more of the exemplary embodiments, the CPU 420, which is configured by executing the client application, takes the video signal and disassembles it in one or more stages into file slice fragments using object storage technology. Generally, object-based storage is a storage architecture that manages data as objects. Each object typically includes the data itself, a variable amount of metadata, and a globally unique identifier.

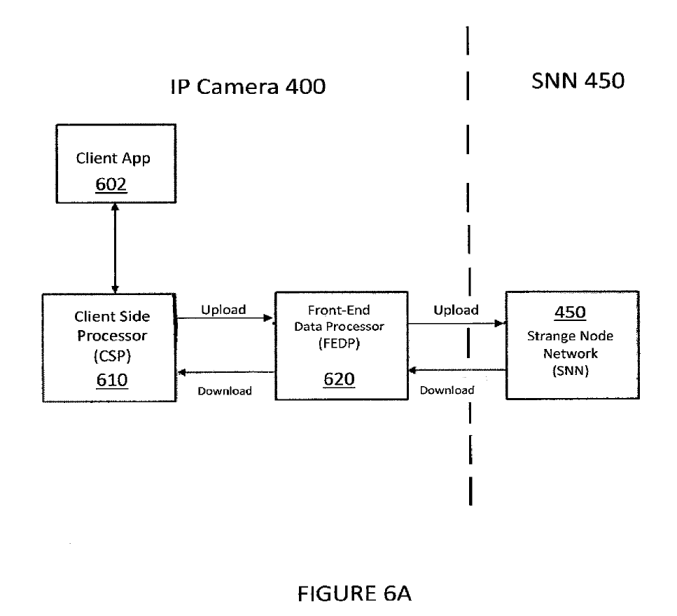

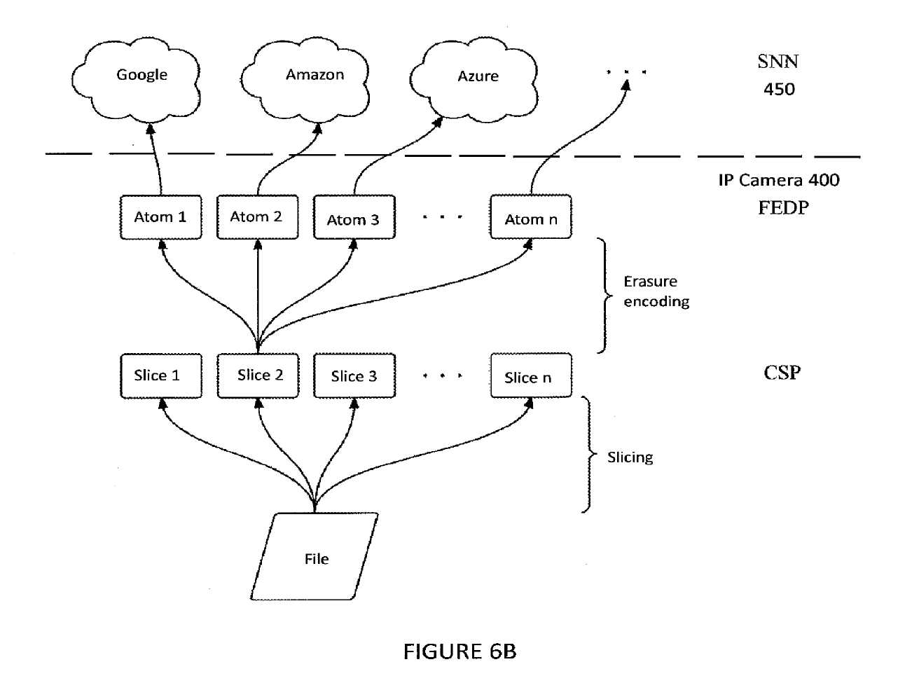

More specifically, the exemplary functions performed by the configured CPU at step 510 are further described in relation to FIG. 6A. FIG. 6A is a block diagram showing an exemplary configuration of logical components or modules operating on the IP camera 400 side of the system that is in communication with to the SNN 450 side of the overall system. As shown, the logical components of the IP Camera can include, for example, a client application 605, a client side processor (CSP) 610 and a front end data processor (FEDP) 620. The operations described as being performed by the CSP and FEDP can be implemented using the CPU, which is configured by executing the client application 605 to perform the CSP and FEDP operations as further described herein.

As a first step, the CSP can split a video file into a number of slices, each of a given size. The number and size of the slices can be varied based on prescribed parameters that can be defined by the client application and according to the particular implementation. The number and size of the slices can be varied via parameters defined by the client app. Each slice can be encrypted with a client key, and assigned a unique identifier. The CSP can also produce a metadata file which maps the slices to allow for their reassembly into the original complete video file. This metadata file can be stored at the client's data center and can also be encrypted and copied into one or more nodes of the SNN. In an exemplary embodiment, the CSP can then send out the sliced files to the next layer, the front end data processor (FEDP), for further processing.

In an exemplary embodiment, the FEDP module of the CPU can also perform further processing on the slices. For instance, the FEDP can take sliced files provided by the CSP and further process each slice. This processing can include further dividing each slice into a series of file slice fragments. Furthermore the file slice fragments can also be optimized for error correction using “erasure coding.” Erasure coding is performed to provide error correction, for example, in the event some data is lost during the transmission process. The erasure coding, as will be further described herein, will increase the size of each file slice fragment, to provide for error correction. The FEDP can also encrypt the file slice fragment using its own encryption key.

Preferably, the FEDP can create a metadata file or add to an existing metadata file. The metadata file is preferably generated to map all of the file slice fragments back to their original slices. In addition, the metadata file can be generated to include a record of which storage nodes network (SNN) servers are used to store which file slice fragments. The fragment and slice mapping information can be stored at the client's data center or other client-side computing devices and can also be encrypted and copied into the SNN. For instance, the map information can be distributed to security offices and other locations that monitor or otherwise access the video feed from the IP camera. In some implementations, such encryption and optimization and error correction preferably occurs before dispersal to a series of storage nodes, as further described herein. Although the steps for separating the video signal into discrete pieces has been described as a two stage process implemented by the FEDP and CSP components of the CPU, it can be appreciated that the steps can be performed in any number of stages and by one or more computing components.

In some implementations, the separation and mapping process implemented by the IP camera at step 510 can also include steps for selection of the distributed storage nodes. More specifically, the configured CPU 420 can determine which nodes in the SNN 450 are to be used to store one or more of the file slice fragments. In some implementations, the nodes used for data storage can be selected to optimize for both speed of data throughput and data security and reliability. Moreover, in some implementations the nodes can be selected by the CPU dynamically during operation, as a function of prescribed parameters defined during set-up, or a combination of the foregoing.

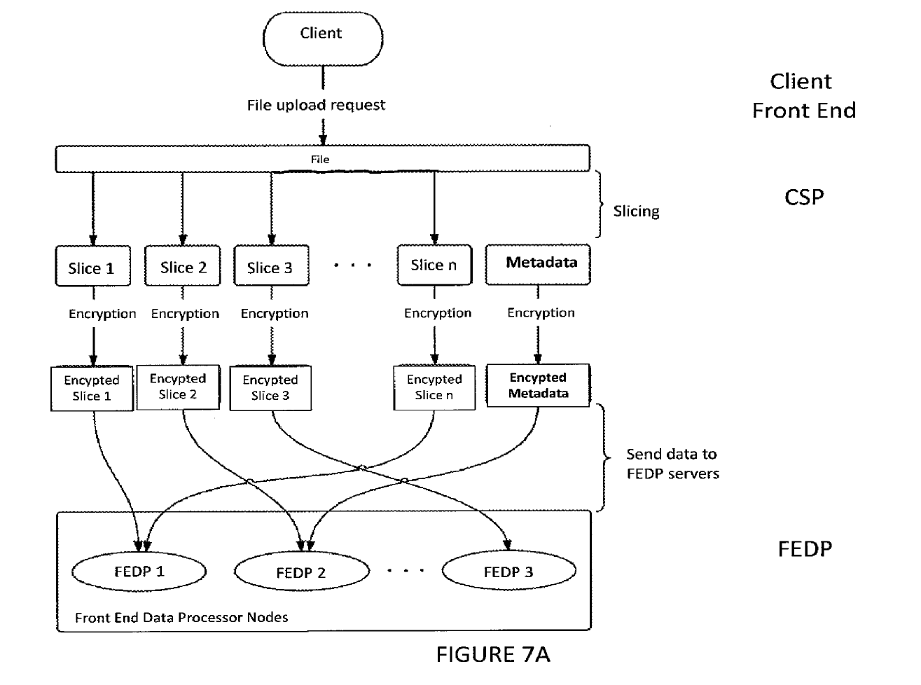

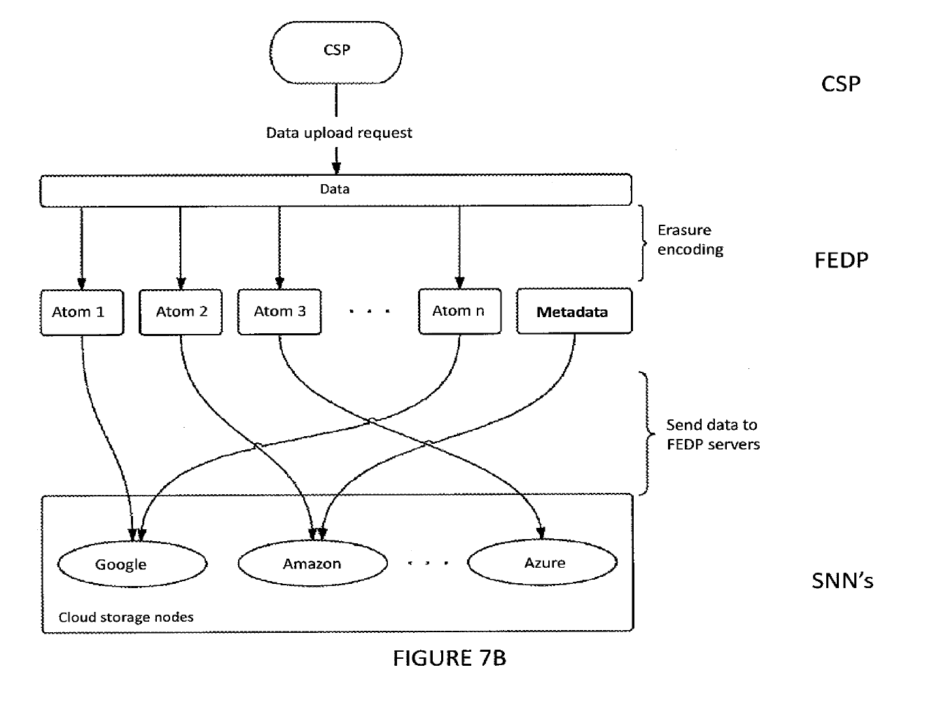

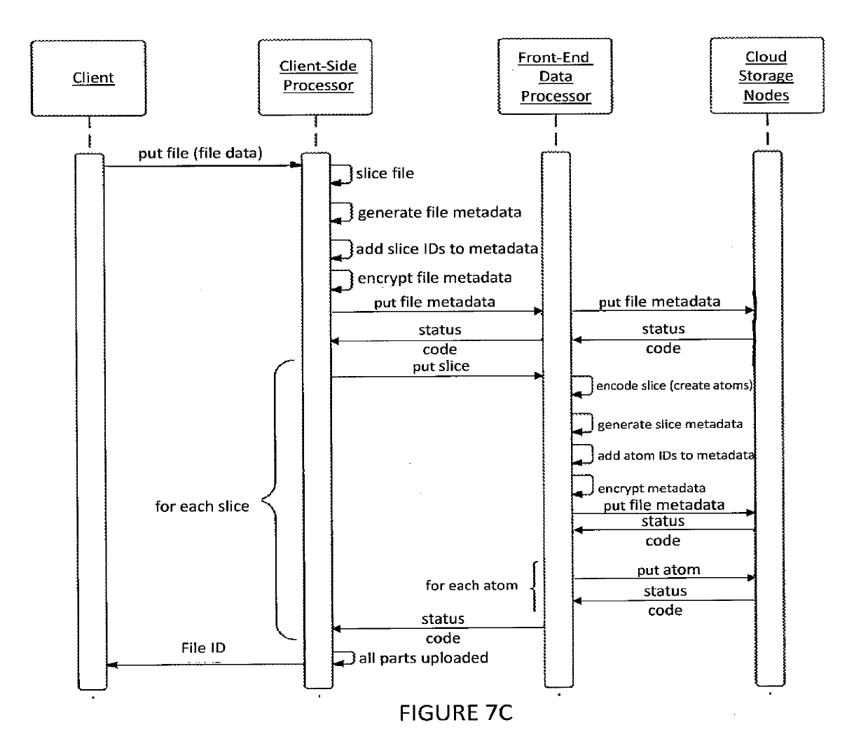

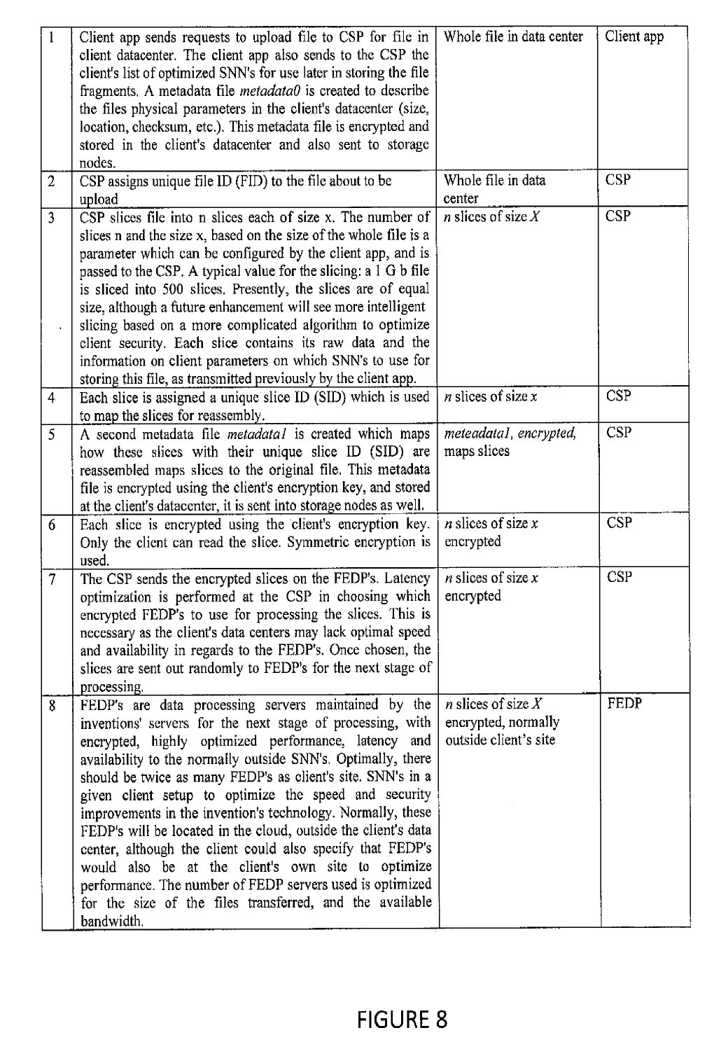

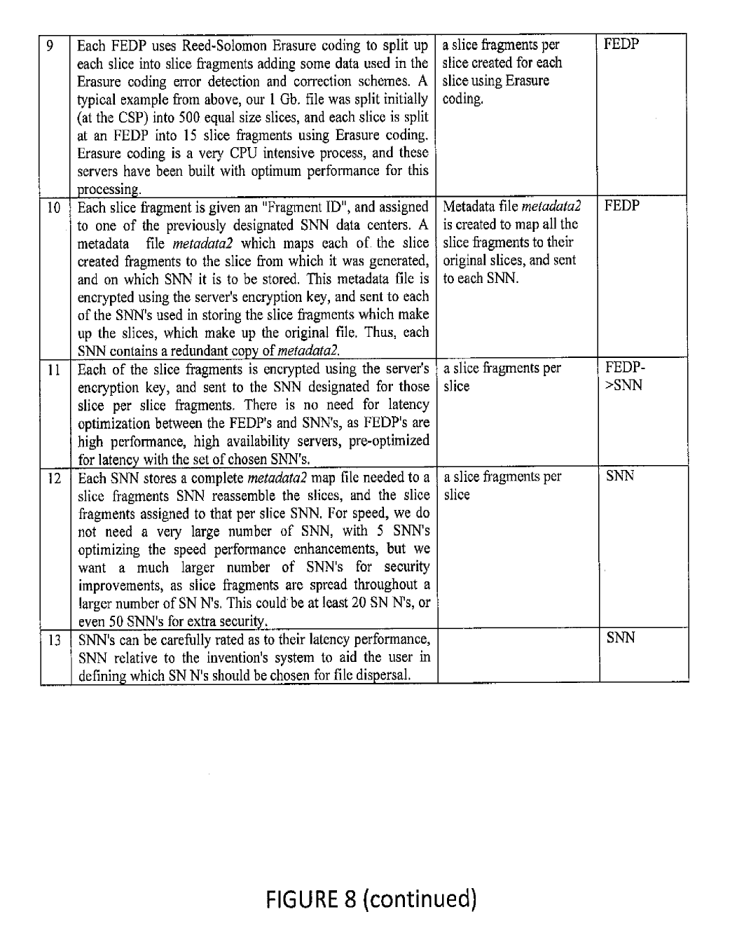

FIG. 6B further illustrates the various stages of file processing discussed above during upload of a file to the SNN according to an exemplary embodiment. FIGS. 7A and 7B respectively show the two basic processing stages during the upload process of a file from a client-side device (e.g., the IP Camera) to the SNN. In particular the figures illustrate the processing at the CSP of a file into file slices, and processing at the FEDP of file slices to create file slice fragments for dispersal to the SNN's. FIG. 7C is another illustration of the upload process in step-by-step fashion, showing some of the intermediate steps. In addition, FIG. 8 is a chart further describing detailed steps that can be included in a file upload process performed by the IP camera in accordance with an exemplary embodiment.

As described above, steps for separating the video file into file slice fragments and erasure coding can be performed by the CPU of the IP camera. In addition or alternatively, certain steps for breaking a file slice into smaller fragments and/or the steps for erasure coding can be implemented by an intermediate layer of one or more file servers configured to, for instance and without limitation, conduct erasure coding on the file slice(s).

Returning to FIG. 5, at step 515, the IP Camera 400 sends groups of file slice fragments to their designated SNN servers. In addition, a copy of the one or more of the metadata files that have been created, or portions thereof, can also be transmitted to each SNN server and/or other client computing systems used to access the video files. This effectively creates a virtual “data device” in the storage servers, which can be on the cloud.

More specifically, the camera can be configured to transfer the discrete pieces in multiple transmission streams to multiple distributed storage nodes. For instance, the video file, which has been broken up into discrete pieces, can be simultaneously transferred in multiple streams to multiple storage nodes around the globe. Multiple data streams maximize utilization and ensure security, as explained below.

As shown in FIGS. 4A and 4B, the CPU 420 can be configured to, using the network interface 435, transmit multiple data streams 440 to a plurality of destination nodes in the SNN 450. In some implementations, each transmission stream is directed to a respective node in the SNN.

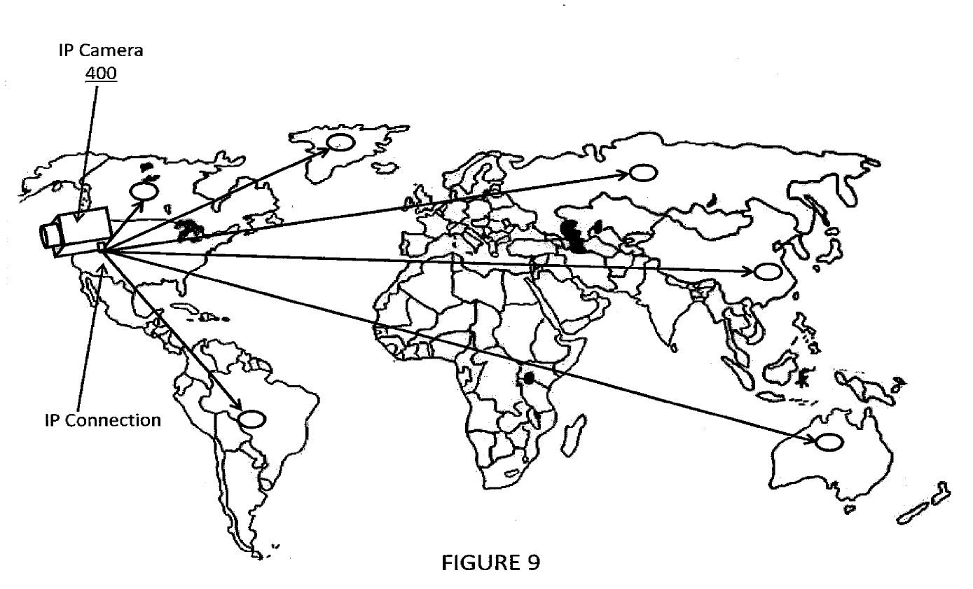

For instance, FIG. 9 is a high level diagram that illustrates multiple communications streams communicatively connecting the IP camera with individual nodes of the SSN that are distributed around the world. It can be appreciated that such channels can be established over one or more respective communication networks, such as the internet.

In some implementations one or more of the discrete pieces can be transmitted in a single stream. Similarly, multiple discrete pieces can be spread across multiple streams. Moreover, the multiple streams can be transferred simultaneously or according to other transmission sequences.

Accordingly, it can be further appreciated that the IP Camera, can communicate with the SSNs over the communications channels and networks using a variety of different possible communications protocols including without limitation internet communication protocols (e.g., Transmission Control Protocol (TCP), User Datagram Protocol (UDP), Internet Control Message Protocol (ICMP), Hypertext Transfer Protocol (HTTP/HTTPS), File Transfer Protocol (FTP) and the like) and other high-level computer communication protocols.

Furthermore, in a preferred implementation, to enhance security, the discrete pieces are generated and dispersed such that no transmission stream includes sufficient data for reconstructing the original media files.

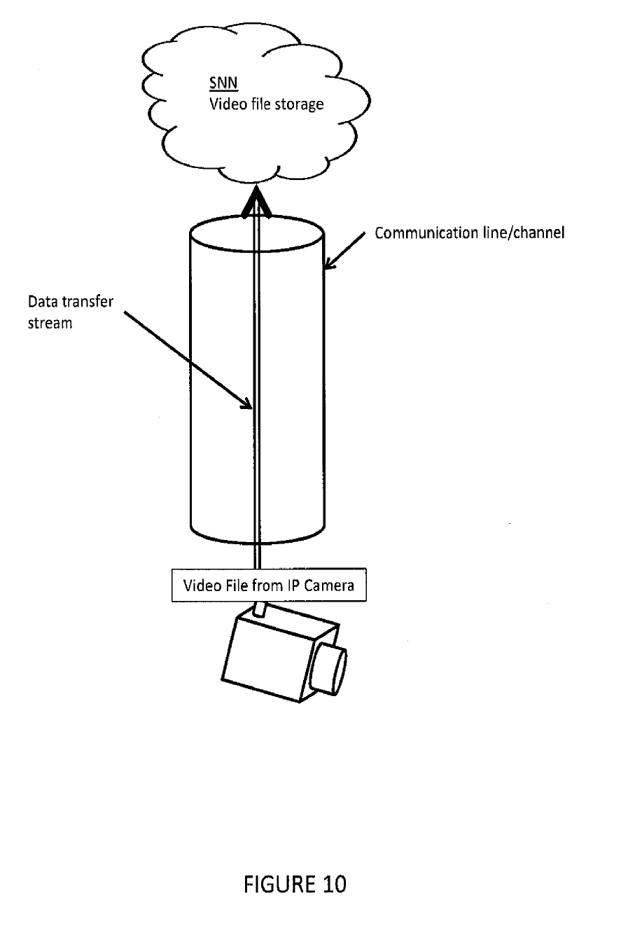

In regard to the transmission of the video file as discrete pieces and using multiple data streams, as noted above, multiple data streams enables the disclosed system to, among other things, maximize utilization. FIG. 10 depicts a conventional system. As shown, the outgoing communication line from the IP Camera defines the maximum bandwidth that is available for use when transferring a file from the IP Camera and the network that it resides on. In addition, the data transfer stream established with a storage network node defines the amount of data that can be moved per second. In most cases the maximum bandwidth of an individual data connection from the local IP network to a particular storage network node is significantly lower than the bandwidth of the overall communication line available to the IP camera. As a result, only a fraction of the available bandwidth can be utilized when transmitting a video to a single node. Current IP Camera technologies do not work well to increase the video transmission speed.

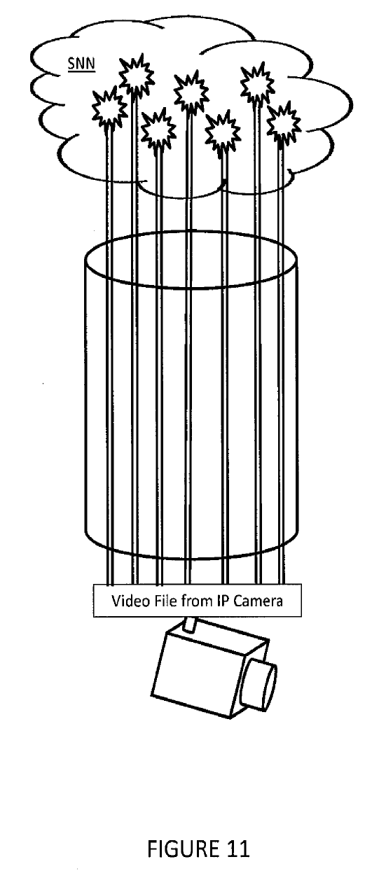

As shown in FIG. 11, the IP camera and storage system configured in accordance with the disclosed embodiments, enable high speed dynamic delivery of data. More specifically, storage is distributed over N nodes, which can include public and private cloud locations. The increased upload (and down load speeds when accessing the stored data) is achieved by transmitting the data through parallel transmission streams to the multiple storage network nodes. Parallel streams maximizes the bandwidth utilization. More specifically, by establishing multiple transmission streams that connect the IP Camera to multiple storage network nodes, the overall bandwidth that can be utilized by the IP Camera is not limited by the bandwidth of any individual transmission stream (e.g., as illustrated in FIG. 10, which depicts a single stream used to transmit a video file to storage). The IP Camera can be configured to define the number of individual transmission streams and also select the recipient storage network nodes in order to utilize the bandwidth available through the communication channel Therefore, the bandwidth is more effectively utilized. As a practical benefit, the improved bandwidth utilization makes it possible to maximize the number of cameras that are used in the system without overloading the IP network. More specifically, because the IP Cameras configured in accordance with the disclosed embodiments more efficiently disperse video data to remote storage, more IP Cameras can exist on a single network and effectively upload the respective video files without exceeding the available bandwidth of the IP Network connection. It can be appreciated that the actual number of IP Cameras that can be implemented on a given IP network would vary depending on parameters of the video data captured (i.e., file sizes) as well as the bandwidth limitations of the IP network.

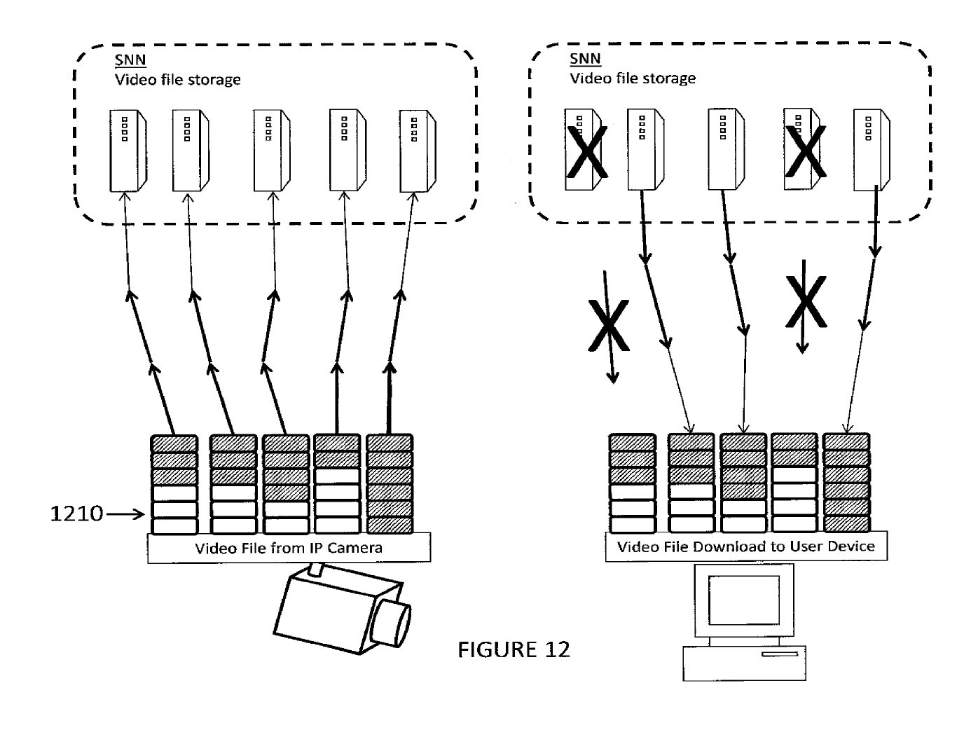

As also noted above, by utilizing multiple data streams with multiple distributed nodes the disclosed embodiments facilitate more secure and fault tolerant systems. FIG. 12 is a high level diagram illustrating storage network nodes and the dynamic delivery of discrete pieces of the IP Camera video file during the upload (left side of FIG. 12) and download process (right side of FIG. 12). As shown in FIG. 12, the failure of certain nodes (identified in FIG. 10 with an “X”) during the download process does not affect the transfer of the discrete pieces from the remaining nodes. Moreover, the use of error correction allows for multiple node failure without loss of critical data. Security is further assured in transit due to the encrypted pieces/fragments. Accordingly, it can be appreciated that, by using multiple data streams, the disclosed embodiments can maximize utilization and ensure security and redundancy.

The multiple number of upload and download nodes used in the system will speed up both uploading and downloading. A further increase in throughput speed can be obtained by optimizing the latency between the IP camera 400 and nodes of the SNN, in other words, choosing the SNNs with the best current latency available. The use of multiple nodes also decreases the overall performance hit seen if one particular server path is suffering from high latency.

In some implementations, the discrete pieces of data can be dynamically managed for optimum delivery route in real time. In particular, as shown in FIG. 12, the CPU 220, which is configured by executing the client application, can be configured to assign the discrete pieces of data for storage by one or more SNN nodes by arranging the discrete pieces into queues 1210. Each queue of data can be designated for transmission by the network interface 235 to a respective storage network node. As noted above, the CPU can dynamically select storage network nodes for storage of the discrete pieces according to a variety of operational parameters and prescribed settings. Similarly, the CPU can also be configured to dynamically assign and re-assign the discrete pieces for storage in one or more storage network nodes. More specifically, the assignment of a discrete piece to a particular queue (i.e., assignment to a particular node) can be based on one or more of: a latency measure of the particular storage network node, a volume of file slice fragments that are already stored by the particular node or that are waiting for transmission in the particular queue, a geographic location of the particular node, the availability of the particular node, and a prescribed redundancy level required for storing the discrete pieces. In addition, the dispersal of data to data storage nodes can also be optimized based on the current throughput conditions for a node. For instance, nodes with the best connectivity can be chosen to store larger amounts of data, thus optimizing the storage nodes available for maximum speed of data transfer during the dispersal process. Additional parameters that can inform the data dispersal process can also include the available bandwidth of the communication channel, the throughput of the individual communication streams with respective nodes, the availability of other communication channels, and any back-log in the queues. It can be appreciated that the management of the data dispersal (e.g., queuing, and routing) can be performed by the CPU based on parameters that are generally consistent (e.g., SNN location, location preferences, redundancy settings, historical throughput/latency metrics, etc.) or parameters that vary during operation (e.g., current node availability, latency, throughput, etc.). These parameters can be measured by the CPU during operation periodically and/or in near-real time. Accordingly, the CPU can be configured to dynamically adjust the distribution of data depending on the dynamic measurement of the aforementioned parameters and the prescribed objectives/settings for the particular application.

In some implementations, if the particular video file is in high demand, there are two main approaches that can be taken to meet the demand. First, a larger number of fragment storage nodes can be employed for dispersal of the erasure encoded data fragments. If the demand is primarily coming from one geographic area, nodes could be chosen for dispersal with the best data throughput rates for either the IP Cameras in that area and/or clients accessing the stored data in that area. Second, a higher level of redundancy can be chosen for the erasure coding step. For example, instead of 30% redundancy, higher levels of redundancy will help ensure greater availability under load. These two steps can be performed dynamically to meet specific demand and load requirements as they occur in real time. In addition, certain slices or fragments can be singled out for greater levels of redundancy to improve availability. Specifically, the first segments of the media file could be given the highest level of redundancy to meet the needs of increased demand.

The data storage techniques described above can be designed to use virtualized servers throughout. For example, 3 virtual servers in parallel could be used instead of one real hardware server to improve performance, and insure hardware independence.

In some implementations, multiple separate communications channels (e.g., physical network connections) can be established between the IP Camera and the storage network nodes. These additional communications channels can be established as back-up lines and/or to provide redundant transmission of one or more of the data streams and any related information. As shown in FIG. 4B, transmitting the multiple data streams 440 can include establishing, using the network interface 435, multiple data communication channels/lines 445 (i.e., channels 445a, 445b and 445c) between the network interface and respective destination nodes. Accordingly, as shown, each data communication channel can be used to transmit a plurality of data streams 440a, 440b and 440c, respectively. It can be appreciated that various schemes can be used to manage transmission of the data elements to the storage nodes. For instance, in the event that a particular communications channel fails, transmission of the discrete pieces originally defined to be transmitted to the SNNs as transmission streams 440a over communications channel 445a can be dispersed through an alternative communications channel, say, channel 445b, as transmission streams 440b. By way of further example, discrete pieces can be transmitted across multiple different communications channels for redundancy based on system and implementation requirements. In addition or alternatively, transmission of the discrete pieces can be spread across different communications channels as well. It should also be appreciated that exemplary processes for optimizing the transmission of data across multiple transmission streams (e.g., node selection, data routing and dispersal and the like based on measured parameters of the various system components, e.g., throughput, latency, etc.) can similarly be implemented by the IP Camera to optimize the transmission of the discrete pieces of data using the multiple communications channels.

Once the fragments are uploaded at step 515, the SNN servers will now host the processed file slice fragments, say, in the cloud at normally available cloud hosting servers, waiting to receive a future request for file download. This creates a “virtual hard drive” device in which a file is not stored in a single physical device, but spread throughout a series of physical devices which contain “fragments” of the file, which are encrypted.

At step 520 the file can be retrieved by a client computing device. The process of downloading a file which has been previously uploaded to the SNN generally involves a reversal of the steps used in the upload process. Access of the video files for the purposes of moving, deleting, reading or editing the file is accomplished by reassembling the file fragments rapidly in real time. This approach gives numerous improvements in speed of data transfer and access, data security and data availability.

As explained above, in one exemplary implementation, the video file of from an IP security camera can be broken up into small file slice fragments in a two-step process. The first step breaks up the whole file (which can be compressed or not compressed) into a series of file slices. These file slices can be encrypted, and a metadata file is created which maps how to assembly the slices into the original file. The second step takes each file slice and breaks it down into smaller data fragments that are erasure coded in accordance with the foregoing techniques to make the original data unrecognizable.

Moreover, as noted above, a client computing device 460 that is configured to access the SNNs system can be provided with one or more metadata files that can include information identifying the file slice fragments, and map all of the file slice fragments back to their original slices. In addition the metadata file can also provide information mapping the slices back into the original video file. Furthermore, the map information can include a record of which storage nodes network (SNN) servers were used to store which file slice fragments. As each slice can be encrypted with a one or more encryption keys the client device can also be provided with corresponding keys for decryption of the fragments or slices as well as the erasure coding protocols so as to perform error correction.

Accordingly, using the map and the corresponding identifiers, the client computing device can retrieve the discrete pieces of data from the respective distributed SNN nodes. Moreover, using the metadata including the map and associated identifiers, the retrieved pieces of data can be decoded and re-assembled. Thus, the client computing device can be used to play, access or otherwise process the re-assembled security video files.

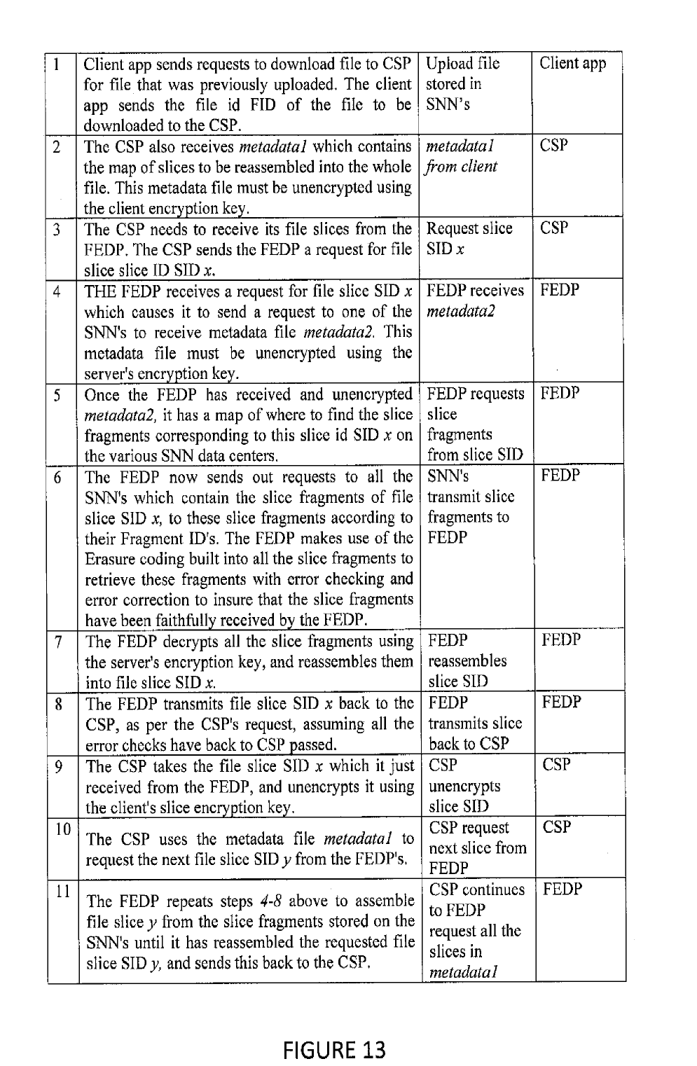

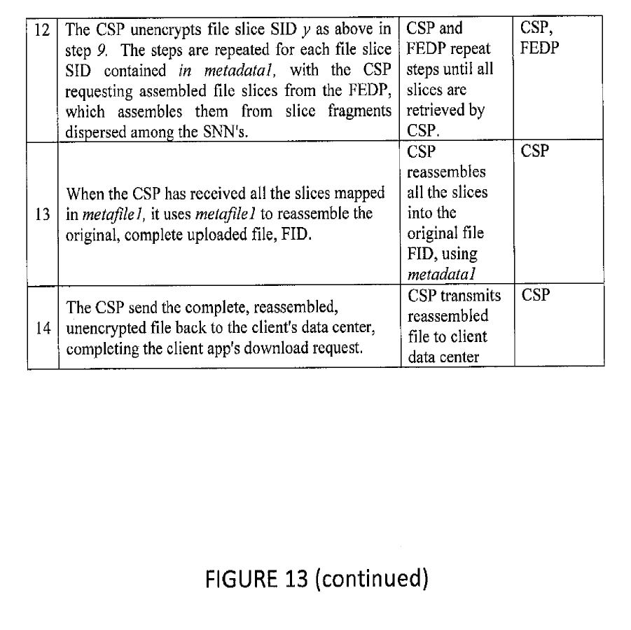

More specifically, in some implementations, the slice fragments which are stored across many SNN's are retrieved and reassembled into file slices using the second metadata file which maps how slice fragments are reassembled into slices. This is done by the client computing device, which can also include an operative FEDP component and a CSP component. The so assembled file slices can then be reassembled by the CSP into a complete video file using the first metadata file which maps how the slices are reassembled into a whole file for output via using the client computing device. The second metadata file can be stored redundantly on each of the SNN's used to store the files, and the first metadata file can also be stored in the client's local datacenter and on each SNN as well. FIG. 13 is a chart further describing detailed steps that can be performed in a file download process using the client computing device in accordance with an exemplary embodiment.

The disclosed technology for processing IP camera video and the distributed storage of the video files presents numerous advantages over existing systems. Among these advantages are the following:

### A. Data Transfer Rates

Compared to existing cloud storage technology, the disclosed embodiments permit substantial improvements in the speed of data transfer under typical Internet communication conditions. Speeds of up to 300 mbps have been demonstrated. This speed improvement stems from several factors.

When reconstructing a file its attendant “pieces” are transferred from/to multiple servers in parallel, resulting in substantial throughput improvements. This can be likened to some of the popular download accelerator technologies in use today, which also open multiple channels to download pieces of a file, resulting in substantial boost in download rates. Latency bottlenecks that might occur in one of the transfer connections to one of the cloud servers do not stop the speedier transfers to the other servers which are operating under conditions of normal latency.

The inherent improvements in data security and reliability stemming from distributed storage eliminates the need for constant mirroring of data read/writes through replication, resulting in further speed improvements to throughput.

In some implementations, the most resource intensive processing of the data can occur at the server side on one or more very high performance servers in the cloud, which are optimized for speed and connectivity to both the cloud server storage sites and the client sites. In particular, erasure coding in certain embodiments can be performed at the server side, for example on multiple data processing servers. These servers can be chosen to have high processing performance, since the erasure coding process is typically a central processing unit (CPU) intensive task. This results in improved performance as compared to erasure coding done at the IP camera side, which can lack the hardware and software infrastructure to efficiently perform erasure coding, or on a single device. Moving such processing to an optimized group of servers decreases the load and performance requirements at the client side.

### B. Data Security

The disclosed “virtual device” storage offers significant improvements in terms of data security over previous designs. By breaking up each media file into many file slice fragments and dispersing the file slice fragments over many cloud storage locations, preferably at geographically dispersed locations, a hacker could find it extremely difficult to reassemble the file into its original form. In addition, the file slice fragments are all encrypted in certain embodiments, adding another layer of data security to confound a would-be hacker. A successful hack into one of the cloud storage locations will not give the hacker the ability to reassemble the full media file. This is a significant improvement in data security over previous designs.

In certain embodiments, the servers used for both processing and storage of file slice fragments can be shared by multiple clients, with no way for a hacker to identify from the data slices to which client they can belong. This makes it more difficult for a hacker to compromise the security of file data stored using this technology. File slice fragments can be dispersed randomly to different cloud storage servers, further enhancing the security of the data storage. In certain embodiments, the client does not know exactly the locations to which all the file slice fragments have been directly dispersed. Also, there is no one place where all the keys are stored to reassemble the file slice fragments and/or decrypt the file slice fragments. Lastly, as an additional enhancement to data security, a two dimensional model of metadata storage can be used, in which metadata needed to reconstruct the data is stored on both the client side and on remote cloud storage servers.

The disclosed improvements in speed and security, and greater utilization of available storage resources enables higher video data transfer rates using today's communications protocols and technologies.

### C. Data Availability

The disclosed “virtual device” storage also offers improvements in the availability of the data, compared to prior art storage technology. By splitting the file into multiple file slice fragments which are stored on a number of different cloud servers, communications problems between the client location and one of the physical cloud locations can be compensated by normal communications with and low latency at other data locations. The overall effect of having file fragments dispersed among multiple locations is to insulate the overall system from outages due to communications disruptions at one of the sites.

The use of many storage nodes for storing file slice fragments greatly increases the security available in the storage of client data. The task of a hacker finding the necessary information to tap into all the disparate slice fragments at a large number of SNN's, and reassemble them into a usable file is very formidable.

The use of erasure coding for the dispersal of the slice fragments adds an extra layer of reliability through its inherent error checking/correction which allows the system to dispense with the need for multiple data replication, with it's inherent performance hits and security risks.

Preferably, the intermediate server processing nodes are all comprised of high performance processors and have low latencies. This results in high availability to the client for data transfers.

Preferably, the intermediate server processing nodes can be chosen dynamically in response to each client request to minimize latency with the client who requests their services. The client can also select from a list of cloud storage servers to be used to store the file slice fragments, and can optimize this list based on his geographical location, and the availability of these servers. This further maximizes data availability for each client at the time of each transfer request.

### D. Data Reliability

The disclosed “virtual device” storage also provides improvements over the prior art in the reliability of a cloud data storage system. Separation of each file into file slice fragments means that hardware or software failures, or errors at one of the physical cloud storage locations will not prevent access to the file, as could be the case if the entire file is stored in one physical location, as in certain previously existing systems.

Further, the use of the erasure coding technology discussed herein insures high quality error correction capabilities in the system, enhancing both data security as well as reliability. The use of erasure coding that makes the original data unrecognizable, and multiple nodes with redundant data adds powerful and secure error correcting technology. Packet loss problems are no longer a relevant consideration. The disclosed technology eliminates the need for full redundant copies of the original video file on multiple servers throughout the service area. The erasure coding adds a pre-defined level of redundancy to the data collection while creating a series of file slice fragments which are then dispersed to a series of file fragment storage nodes. Optimal redundancy of 30% or higher is desired for the erasure coding used in this process. If the media file is frequently accessed, the system can increase file object redundancy of particular slices.

### E. Use of Existing Cloud Infrastructure Resources

Elements of the disclosed subject matter can make use of existing cloud server infrastructures, with both public and private resources. Current cloud providers can be setup with their existing hardware and software infrastructure for use with the disclosed methodology. Most of the enhancements offered by the technology disclosed herein can therefore be available with minimal investment, as currently existing cloud resources can be used either without modification or with minimal modification.

Further, the servers used for both processing and storage of file slice fragments can be shared by multiple clients, with no way for a hacker to identify from the slices to which client it belongs. This makes it more difficult for a hacker to compromise the security of media file data stored using this technology.

### F. Reduction of Storage Infrastructure Cost

Certain embodiments require far less redundancy compared to existing cloud storage technology solutions. As mentioned above, previous storage systems can require as much as 500% additional storage devoted to mirroring and replication. The embodiments disclosed herein can operate successfully with only a 30% redundancy over the original file size because of their higher inherent reliability. Even with only 30% redundancy, higher levels of reliability over existing systems can be achieved. The reduced necessity for high redundancy results in lower costs for cloud storage capacity.

To summarize, in an exemplary embodiment, the IP Camera video processing/encoding and distributed storage technology disclosed herein accomplishes the following fundamental tasks:
1) Splitting of an IP camera video file into pieces or file slices which can also be broken up further into file fragments that are erasure coded to provide unrecognizable pieces.
2) Creation of maps of the file slices which describe how the files were split to allow for re-assembly of the data at a client computer. This map is stored in a metadata file.
3) Optional encryption of the file slices for additional data security.
4) Optional compression of the file slices to reduce the size of data storage and improve transfer speed.
5) Erasure coding of the file slices to enable enhanced error correction and data recovery. The slices are divided into file slice fragments by the erasure coding process.
6) Creation of a map of the file slice fragments needed to reassemble them into file slices. This map is stored in a second metadata file.
7) Optional encryption of the file slice fragments for additional data security.
8) Optional compression of the file slice fragments to reduce storage space requirements and improve transfer speed.
9) Decoding on the client device of the file slice fragments and re-assembly into file slices, and then into the whole video file, for playing on the client media player (or browser). Note that the fragments must be assembled into slices in the proper order, and the slices must be assembled into the whole file in the proper order. The client software uses the mapping information provided by the two metadata files to reassemble the video file in these two stages.

The basic structure of this technology can be visualized as being implemented by the following operative elements:
1. The CSP (see, FIG. 6A) of the IP Camera slices the video file into file slices, optionally encrypts the slices, and generates a meta-data file with a map of how the slices can be re-assembled into the original media file. The meta-data file also maintains information on the order of each file slice needed to assemble the slices in the proper order.
2. The FEDP (see, FIG. 6A) of the IP Camera breaks each file slice into file slice fragments using erasure coding that produces unrecognizable pieces. In an exemplary embodiment erasure coding adds 30% of data redundancy. A second meta-data file maps how the file slice fragments are reassembled into to file slices. The second meta-data file also maintains information on the order of each fragment needed to assemble the slices in the proper order, during playing of the fragments on the client device.
3. The SNNs are the various storage nodes used to disperse the data fragments. The storage nodes are not necessarily all servers in the cloud. The nodes can be a data center, a hard disk in a computer, a mobile device, or some other multimedia device capable of data storage. The number and identity of these storage nodes can be selected to optimize the latency and security of the storage configuration with nodes having the lowest average latency and best availability.
4. An end-user client decoder (ECD) that can be implemented for accessing and reconstructing video content files. This fourth layer initiates a request to the media host entity for access to the video file(s), and then receives mapping files derived from the two meta-data files generated during storage, above which allow the ECD to retrieve and assemble the file slice fragments into slices, and the slices into the original video file, for the playback or storage of the video file. As evident, the video file should be assembled in the proper order needed for on demand playing of the media content.

While this specification contains many specific implementation details, these should not be construed as limitations on the scope of any inventions or of what can be claimed, but rather as descriptions of features specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described. Other embodiments are within the scope of the following claims. In some cases, the actions recited in the claims can be performed in a different order and still achieve desirable results. In addition, the processes depicted in the accompanying figures do not necessarily require the particular order shown, or sequential order, to achieve desirable results. In certain implementations, multitasking and parallel processing may be advantageous.

1-4. (canceled)

5. A method for transmitting signals securely from an IP camera, the method comprising:
disassembling, using one or more processors of the camera, an output video signal received from a processing unit inside said camera into file slice fragments using object storage technology;
generating metadata for reassembly of the output video signal from the file slice fragments, wherein the generated metadata includes information that enables a processor to retrieve a plurality of the file slice fragments from respective storage network nodes and reassemble the retrieved file slice fragments into the output video signal; and
transmitting, using the one or more processors and a communication network interface of the camera, the file slice fragments among multiple distributed storage network nodes, wherein the file slice fragments are transmitted over a communication network using multiple transmission streams, and further wherein no single transmission stream has sufficient data for reconstructing said output video signal.

6. The method of claim 5, further comprising: encoding the file slice fragments using an erasure coding algorithm, wherein the encoded file slice fragments are optimized for error correction and the output video signal is not recognizable from the file slice fragments.

7. The method of claim 5, further comprising: encoding the file slice fragments that are dispersed to the multiple distributed storage network nodes with at least a portion of the metadata.

8-17. (canceled)

18. An IP camera configured to transmit signals securely over an IP communication network, the camera comprising:
an imaging component including a lens, an image sensor configured to capture video imagery and one or more signal processing units configured to generate an output video signal from the captured imagery;
a non-transitory memory having a software application in the form of machine readable instructions stored therein;
a network interface configured to connect the IP camera to a communication network; and
one or more processors coupled to the imaging component and the network interface, wherein the one or more processors execute the client software application and are configured to:
receive the output video signal from the imaging component and disassemble the output video signal into discrete file slice fragments using object storage technology, and
disperse, using the network interface, the file slice fragments among multiple distributed storage network nodes using multiple transmission streams, wherein the transmission streams are transmitted over the communication network and wherein no transmission stream has sufficient data for reconstructing said output video signal.

19. The IP camera of claim 18, wherein the one or more processors are further configured to:
generate metadata for the reassembly of the output video signal from the file slice fragments; and
transmit the file slice fragments to the multiple storage network nodes wherefrom the file slice fragments can be retrieved using the metadata and reassembled into the output video signal.

20. The IP camera of claim 19, wherein the metadata maps each of the file slice fragments to a respective storage network node among the multiple distributed storage network nodes.

21. The IP camera of claim 20, wherein the one or more processors are further configured to:
transmit at least a portion of the metadata to one or more of the storage network nodes; and
transmit at least a portion of the metadata to a user computing device configured to access and reassemble the file slice fragments into the output video signal, and wherein the metadata enables the user computing device to retrieve a plurality of the file slice fragments from respective storage network nodes and reassemble the retrieved file slice fragments into the output video signal.

22. An IP camera configured to transmit signals securely over an IP communication network, the camera comprising:
an imaging component including a lens, an image sensor configured to capture video imagery and one or more signal processing units configured to generate an output video signal from the captured imagery;
a non-transitory memory having a client application in the form of machine readable instructions stored therein;
a network interface configured to connect the IP camera to a communication network; and
one or more processors coupled to the imaging component and the network interface, wherein the one or more processors execute the client software application and are configured to:
receive the output video signal from the imaging component and separate the output video signal into discrete pieces by disassembling the output video signal into file slice fragments using object storage technology;
generate metadata for the reassembly of the output video signal from the file slice fragments; and
disperse, over the communication network using the network interface, the file slice fragments among multiple distributed storage network nodes using multiple transmission streams, wherein no single transmission stream has sufficient data for reconstructing said output video signal.

23. The IP camera of claim 22, wherein the one or more processors are further configured to encode the file slice fragments using an erasure coding algorithm and to generate a plurality of unrecognizable file slice fragments, wherein the unrecognizable erasure encoded file slice fragments are optimized for error correction and the output video signal is not recognizable from the file slice fragments.

24. The IP camera of claim 22, wherein the one or more processors are further configured to encode the file slice fragments that are dispersed to the multiple distributed storage network nodes with at least a portion of the metadata.

25. The IP camera of claim 22, wherein the one or more processors are further configured to:
select the multiple storage network nodes from a plurality of available storage network nodes; and
establish, using the network interface, one or more transmission streams with each of the selected storage network nodes over the communication network.
